(19) United States
(12) Patent Application Publication
(10) Pub. No.: US 2011/0186532 A1
(43) Pub. Date: Aug. 4, 2011

(54) DEVICE OF MOVABLE PATCH PANEL AND METHOD FOR MANIPULATING THE SAME

(75) Inventor: Yan Jin Wu, Taipei County (TW)

(73) Assignee: DAN-CHIEF ENTERPRISE CO., LTD., Taipei County (TW)

(21) Appl. No.: 12/908,040

(22) Filed: Oct. 20, 2010

(30) Foreign Application Priority Data
Feb. 3, 2010 (TW) 099103256

(51) Int. Cl. H05K 7/18; A47B 96/00

(52) U.S. Cl. 211/26; 312/324

(57) ABSTRACT

A device of a patch panel and a method for manipulating the same are provided. The device includes a first elongated panel which has a first mounting part, and a second elongated panel which has a second mounting part. The second elongated panel is pivotally connected with the first elongated panel.

### FIELD OF THE INVENTION

The present invention relates to a device of a patch panel and a method for manipulating the same, and more particularly to a device having two elongated panels linked by hinges, so as to form a patch panel and a manipulating method for the same.

### BACKGROUND OF THE INVENTION

Generally, there are plural Hubs mounted into a cable rack used for transmitting the network signals. The rack connects many inner network cables for the sake of many persons who can share a network cable connected to the external network. The plural patch panels must be set up for managing many inner network cables and mounting plural patches. If there is one computer being unable to surf the internet, it is capable to find out which network cable has a breakdown in the connection to cause the failure of the network, so that the breakdown cable could be found out effectively. There are plural keystone jacks mounted on each patch panel for inserting the plugs into the jacks. The plugs are disposed at one end of the patch panel. Referring to FIG. 1, it is shown a “V” shaped patch panel frame 10, which is a U.S. invention patent entitled of the “angled patch panel with cable support bar for network cable racks” and issued as U.S. Pat. No. 6,918,786 B2.

Please directed to FIGS. 1 and 2 simultaneously, the frame 10 includes an outwardly angled central frame 11, plural panel openings 12 and a mounting plate 14 having plural mounting apertures 13. A flat centerpiece 15 is located midway along frame 11 and a “V” shaped patch panel frame 10 is combined with a cable support bar 16. An included angle θ between the back of a first panel 171 and the back of a second panel 172 of frame 10 is almost 120° degrees. Frame 10 is mounted at a first and a second fixing position 21, 22 of a rack body 23 of a network cable rack 20. Since the numbers of cables are numerous and jumbled in the rack, the maintenance worker usually walks to the back of rack 20. This is due to the worker would feel very trouble for him to loosen the screws of frame 10 on both first and second fixing position 21, 22 for removing whole frame 10 while some cables are being maintained. If the maintenance worker only loosens the screw on first fixing position 21 of first panel 171, the first panel 171 cannot be removed alone yet for this frame 10 under the condition. So the maintenance efficiency can not be promoted indeed. And the same condition happens when the worker wants to mount the plural keystone jacks on first and second panels 171, 172. The rack 20 is also called a cabinet, the space may be very small and very dark in the rear of some cabinets. It is not very convenience for one to work under the dark and narrow circumstance.

Therefore, how to improve the problems of the worker having to walk to the back of rack in order to perform the maintenance are solved in the present invention. The inventor endeavors in the experiments, tests and researches to obtain a device of a patch panel and a method for manipulating the same, which not only resolves the drawback of having to walk to the back of the rack for avoiding the trouble of loosening all the screws on the first and the second fixing positions for maintenance, but also achieves the convenience that the maintenance is speedy. Namely, the technical issues to be resolved in the present invention are how to overcome the problem that all the screws loosened on the first and the second fix positions in maintenance and consequently the frame can be maintained in a pattern of more speed to move, how to overcome the problem that the revolve is merely aimed to the second elongated panel, and how to overcome the problem that it is not easy to fold the first and second elongated panels at revolving.

### SUMMARY OF THE INVENTION

The present invention relates to a device of a patch panel. The device includes a first elongated panel which has a first mounting part, and a second elongated panel which has a second mounting part and pivotally connected with the first elongated panel.

Preferably, the panel device is a crooked patch panel so as to facilitate the second elongated panel to be rotated directly when the first elongated panel is immovably fixed.

Preferably, the panel device further includes a hinge, the crooked patch panel is a “V” shaped patch panel, and the first and the second elongated panels are connected pivotally by using the hinge.

Certainly, the first elongated panel of the device can have a first holding part, the second elongated panel has a second holding part, and the hinge can include the first holding part, the second holding part and a first pin for combining the first and the second elongated panels to form the patch panel.

Certainly, the first elongated panel of the device can further include a first main body and a first connecting mounted between the first main body and the first holding part, a first obtuse angle is formed between the first connecting part and a first body of the first main body, the second elongated panel further comprises a second main body and a second connecting part mounted between the second main body and the second holding part, and a second obtuse angle is formed between the second connecting part and the second main body so that the first and the second elongated panels can be collapsed together.

Preferably, the device further includes a 0°˜240° included angle, the included angle is formed by the first main body and the second main body.

Preferably, the first pin of the device includes an upper pin half, a central sleeve and a lower pin half, the central sleeve has a first and a second apertures, and the first and the second apertures are inserted by the upper pin half and the lower pin half respectively.

Preferably, the device further includes a second pin, wherein the central sleeve further includes a central aperture, the second pin includes a fixing pin and a fixing fixture having a fixing aperture, and the fixing pin and the fixing fixture are mounted into the central aperture for turning the second elongated panel with respect to the first elongated panel.

Certainly, the first pin of the device can include an upper fixing part and a lower fixing part, the second pin includes a fixing plate, the upper fixing part and the lower fixing part are fixed on the first elongated panel, and the fixing plate is fixed on the second elongated panel.

Certainly, the device can further include a left pin, a right pin, a left fixing piece and a right fixing piece for flexibly adjusting an application width of the patch panel.

Preferably, the first and the second elongated panels of the device are rotated via the left pin and the right pin respectively so as to adjust the application width of the patch panel between 19 inch and 23 inch.

Certainly, the first and the second mounting parts can be rectangular openings, and plural keystone jacks are mounted into the rectangular openings.

Certainly, the plural keystone jacks of the device can be arranged to be interlaced between a higher position and a lower position.

Preferably, the device further includes a cable support frame for receiving plural network cables.

Preferably, the device further includes a lock piece and a connecting rod for fixing the cable support frame on the device.

Certainly, the device can further include a multimedia connector and a modular multi-port panel module mounted on the first and the second mounting parts respectively, wherein the modular multi-port panel module has an insulation displacement connector for connecting an external cable.

According to other feasible point of view, the present invention covers a method for manipulating a panel device having a first and a second elongated panels, each of which has at least a mounting part, the method includes steps of pivotally connecting the first elongated panel with the second elongated panel, determining a wiring demand, and releasing one of the first and the second panels in response to the wiring demand so that the panel device is released in a more convenient way.

Preferably, the wiring demand of the method is a network wiring demand, and the network wiring demand includes a replacement of a keystone jack, a confirmation of a wire connection and an impact of the keystone jack.

According to other feasible point of view, the present invention is a rack for mounting a network Hub, includes a rack body, and a panel device mounted in the rack body and including a first and a second elongated panels, wherein the second elongated panel is pivotally connected with the first elongated panel.

Certainly, the first and the second elongated panels of the rack can have a first and a second mounting parts respectively.

By way of the above-mentioned explication of the concept, it can be known the operation of the device of a patch panel and the method for manipulating the same, which can utilize the second elongated panel pivotally connected with the first elongated panel, and the second elongated panel being able to turn on the condition of the first elongated panel fixed, and the feature of utilizing a hinge to connect the first and the second elongated panel pivotally for turning the single panel directly. The foregoing and other features and advantages of the present invention will be more clearly understood through the following descriptions with reference to the drawings.

### BRIEF DESCRIPTION OF THE DRAWINGS

FIG. 1 is a perspective schematic diagram of the patch panel frame and the support bar according to the prior art;

FIG. 2 is a perspective schematic diagram of the network cable rack of the frame shown in FIG. 1 according to the prior art;

FIG. 3 is a perspective schematic diagram of the preferred embodiment of the device of the patch panel according to the present invention;

FIG. 4 is an exploded schematic diagram of the of the patch panel and the cable support bar shown in FIG. 3;

FIG. 5 is a perspective schematic diagram of the first and the second openings of the patch panel shown in FIG. 3;

FIG. 6 is a top view schematic diagram of the patch panel shown in FIG. 5;

FIG. 7 is a top view schematic diagram of the 45° included angle formed by the first and the second elongated panels of the patch panel shown in FIG. 3;

FIG. 8 is a top view schematic diagram of the 0° included angle formed by the first and the second elongated panels of the patch panel shown in FIG. 5;

FIG. 9 is a perspective schematic diagram of the 24 keystone jacks mounted on the patch panel shown in FIG. 8;

FIG. 10 is a perspective schematic diagram of the patch panel combined with the cable support bar and mounted on the rack shown in FIG. 4;

FIG. 11 is an exploded schematic diagram of another preferred embodiment of the device of the patch panel according to the present invention;

FIG. 12 is an enlarged schematic diagram of the first and the second axes shown in FIG. 11;

FIG. 13 is a perspective schematic diagram after the combination of the panel shown in FIG. 11;

FIG. 14 is a perspective schematic diagram of the second elongated panel turned 180° shown in FIG. 13;

FIG. 15 is a perspective schematic diagram of the second elongated panel turned 90° shown in FIG. 13;

FIG. 16 is a perspective schematic diagram of a 145° included angle formed by the first and the second panel shown in FIG. 13;

FIG. 17 is a top view schematic diagram of the included angle as the width of the patch panel is adjusted to 19 inches shown in FIG. 13; and

FIG. 18 is a top view schematic diagram of the included angle as the width of the patch panel is adjusted to 23 inches shown in FIG. 13.

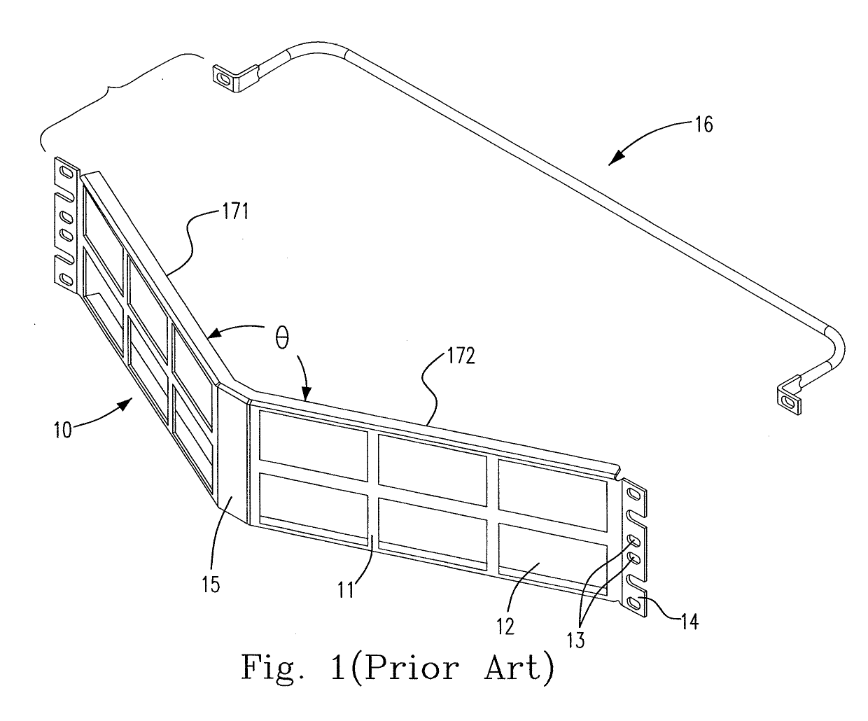

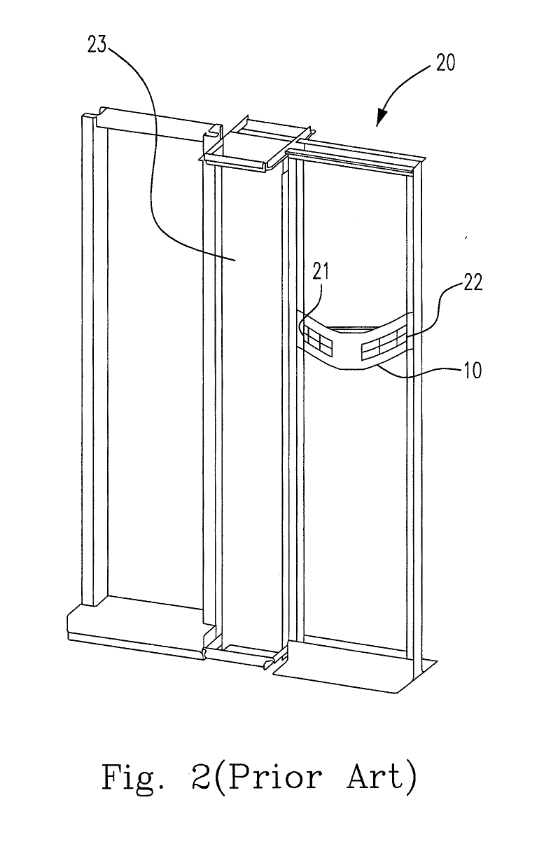

### DETAILED DESCRIPTION OF THE PREFERRED EMBODIMENT

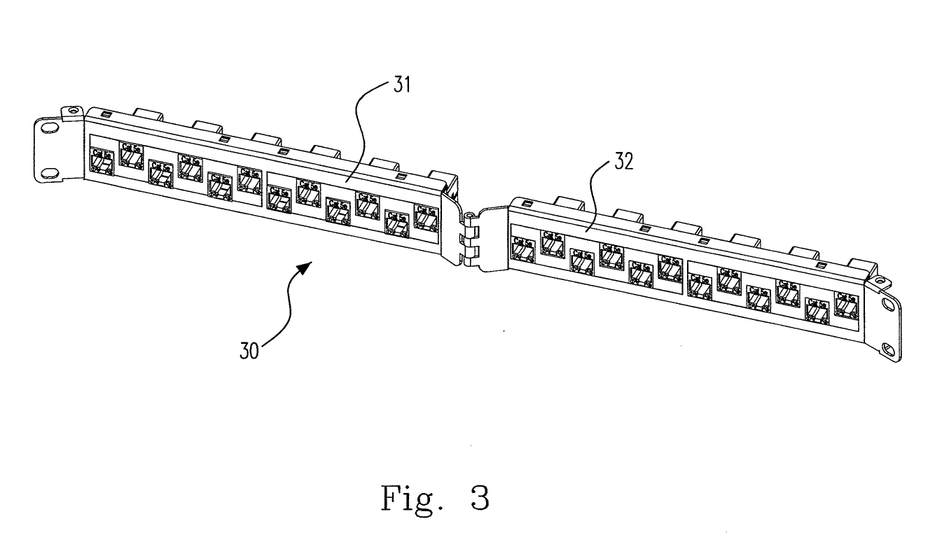

Referring to FIG. 3, it illustrates a device of a patch panel (which is a crooked (arched) patch panel, for example, a frame of a “V” shaped patch panel 30). The device includes a first elongated panel 31, and a second elongated panel 32. Second elongated panel 32 is able to pivotally connect with first elongated panel 31 by pivotally connecting first and second elongated panel 31, 32 pivotally, so as to facilitate second elongated panel 32 to be rotated directly when first elongated panel 31 is immovably fixed, which forms a movable patch panel 30.

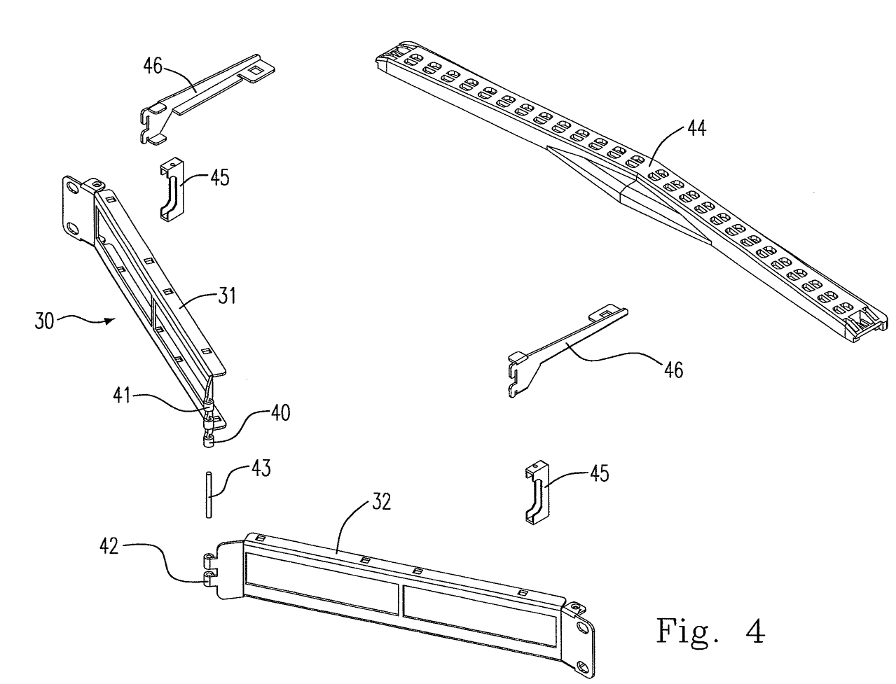

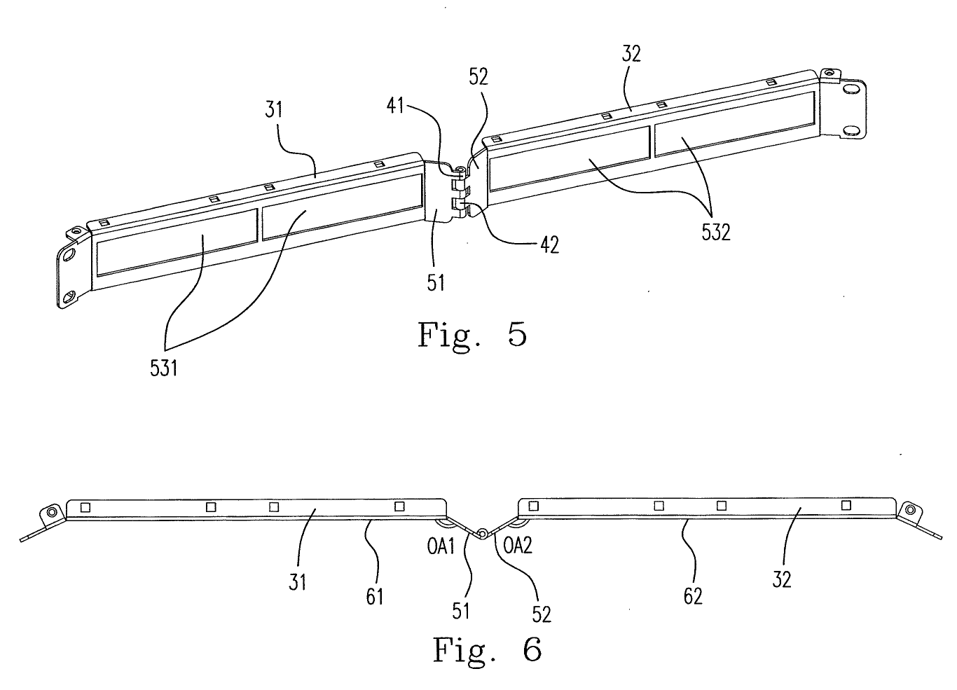

Referring to FIG. 4, device 30 further includes a hinge 40 to connect first and second elongated panels 31, 32 pivotally. First elongated panel 31 has a first holding part 41, second elongated panel 32 has a second holding part 42, and hinge 40 includes first holding part 41, second holding part 42 and a first pin 43 for combining first and second elongated panels 31, 32 to form patch panel 30. Patch panel 30 further includes the mounting of a cable support frame 44 for receiving plural network cables. Cable support frame 44 uses two lock pieces 45 and two connecting rods 46 for fixing cable support frame 44 on the device. Referring to FIG. 5, first elongated panel 31 includes a first connecting part 51, and second elongated panel 32 has a second connecting part 52. Two first and two second mounting parts 531, 532 are two rectangular openings. First and second elongated panels 31, 32 are long and narrow.

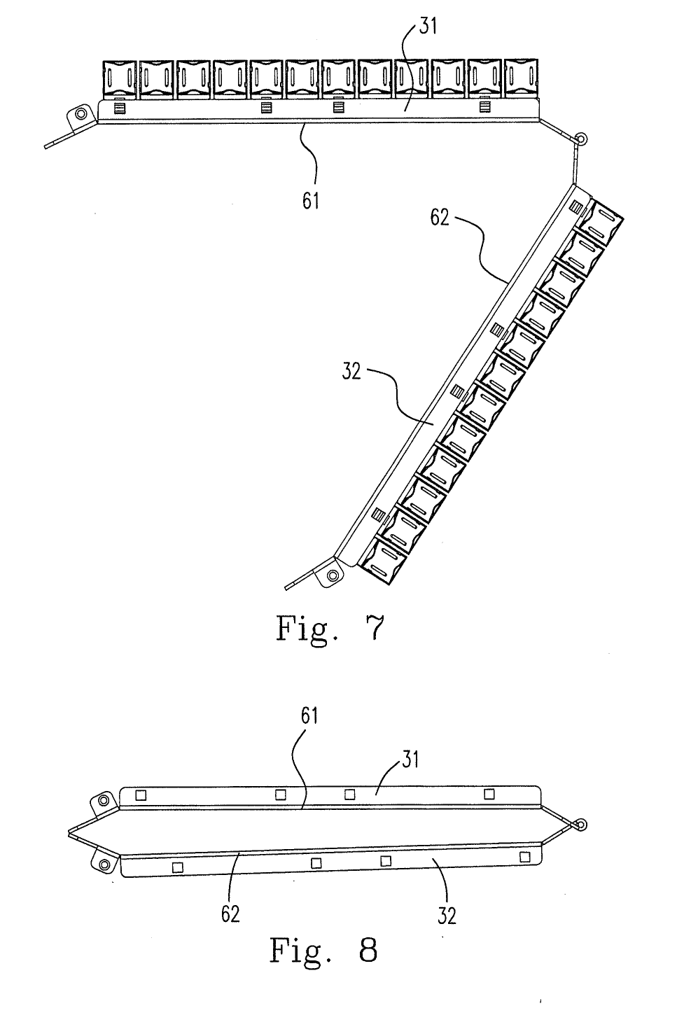

First elongated panel 31 further includes a first main body 61 as showed in FIG. 6, first connecting part 51 mounted between first main body 61 and first holding part 41, a first obtuse angle OA1 is formed between first connecting part 51 and first main body 61. Second elongated panel 32 includes a second main body 62, second connecting part 52 mounted between second main body 62 and second holding par 42, and a second obtuse angle θA2 is formed between second connecting part 52 and second main body 62 so that first and second elongated panels 31, 32 can be collapsed together, and at meantime a 180° included angle is formed by first main body 61 and second main body 62. The device further includes a 0°˜240° included angle, and first and second main bodies 61, 62 have faces. Referring to FIG. 7, a 45° included angle can be formed by first main body 61 of first elongated panel 31 and second main body 62 of second elongated panel 32, one worker does not need to walk close to the rear of the rack 20 again. The steps of the installation for the keystone jacks are as follows:

1. V-shape patch panel 30 is fixed on rack 20 with only second elongated panel 32 secured.

2. Pull 12 bulk cables from the rear of rack 20.

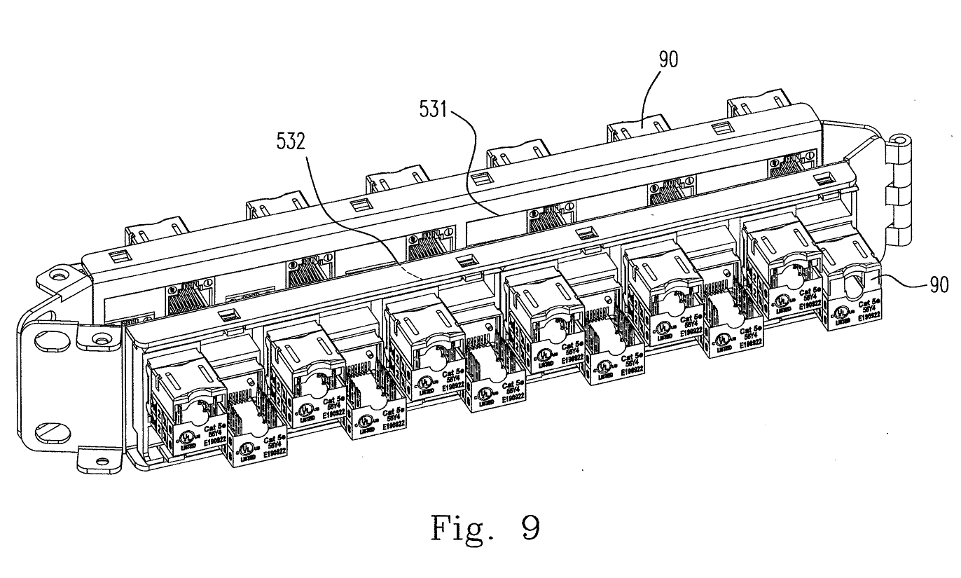

3. Terminate each cable with a keystone jack 90 in FIG. 9 from port 1 to port 12 individually.

4. Half of installation is completed once 12 terminated keystone jacks 90 are loaded back into first elongated panel 31.

5. First elongated panel 31 follows to be fixed on rack 20 and second elongated panel 32 is loosened.

6. Second elongated panel 32 would be turned to form a 45° included angle with first elongated panel 31. Then we can repeat step 1 step 4 for another 12 terminated keystone jacks 90 loaded back into second elongated panel 32. Finally, second elongated panel 32 is turned back and fixed on rack 20 again. A 0° included angle is formed by first main body 61 of first elongated panel 31 and second main body 62 of second elongated panel 32 in FIG. 8. Referring to FIG. 9, both first and second rectangular openings 531, 532 mount 6 keystone jacks 90, and 6 keystone jacks 90 mounted into rectangular openings 531, 532 are arranged to be interlaced between a higher position and a lower position.

Furthermore, the independent pattern of each printed circuit board of 6 keystone jacks 90 could be transformed into a module pattern of a sharing circuit board. Optionally, the keystone jack 90 is not used for promoting the quality of the signal transmission, and four multimedia connectors (e.g. a coaxial joiner adaptor, a ST adaptor, an A/V adaptor and a HDMI adaptor, not shown) and a modular multi-port panel module (e.g. a module with 6 jacks or 8 jacks, not shown) are mounted on the first and the second mounting parts respectively, the modular multi-port panel module has plural Insulation Displacement Connectors (IDC) for connecting an external cable (not shown). The outer cable is utilized for the input of signals to patch panel 30 from the user. The patch panel 30 can be also transformed into a panel (not shown) having the jacks for connecting the F plug of the coaxial cable or the signal plug of another pattern. This panel would be utilized for the multimedia jacks.

According to other feasible point of view, the present invention covers a method for manipulating “V” shaped patch panel 30 having first and second elongated panels 31, 32, each of which has at least a mounting part (e.g. first and second rectangular openings 531, 532), the method includes steps of pivotally connecting first elongated panel 31 with second elongated panel 32, determining a wiring demand (e.g. a network wiring demand of dealing with second elongated panels 32), and releasing one of first and second elongated panels 31, 32 in response to the wiring demand so that the panel device is released in a more convenient way (e.g. the way for second elongated panel 32 turned directly away second fixing position 22 of rack 20 on the condition of first elongated panel 31 fixed on first fixing position 21, and second elongated panel 32 turned directly back to second fixing position 22 on the condition of first elongated panel 31 fixed).

The method can further include a step of unlocking one of first and second elongated panels 31, 32 for managing the wiring demand, and re-locking the one of first and the second elongated panels 31, 32 after fulfilling the wiring demand. The wiring demand of the method is a network wiring demand, and the network wiring demand includes a replacement of a keystone jack, a confirmation of a wire connection and an impact of the keystone jack.

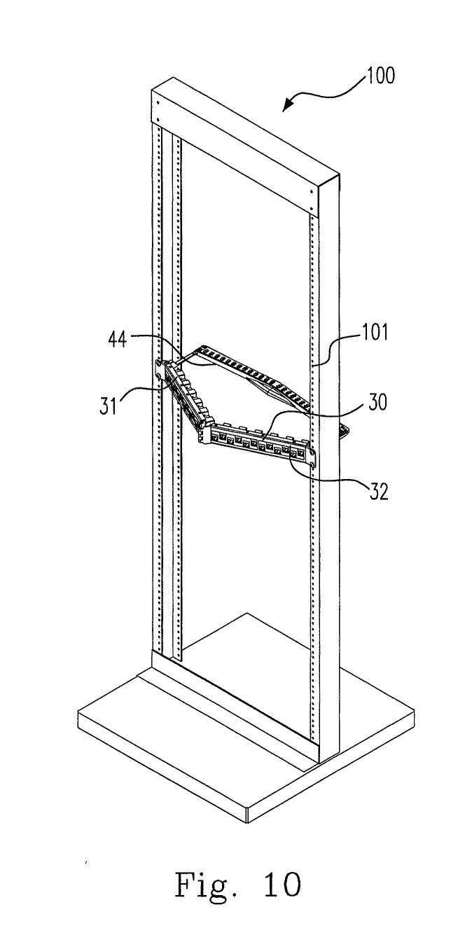

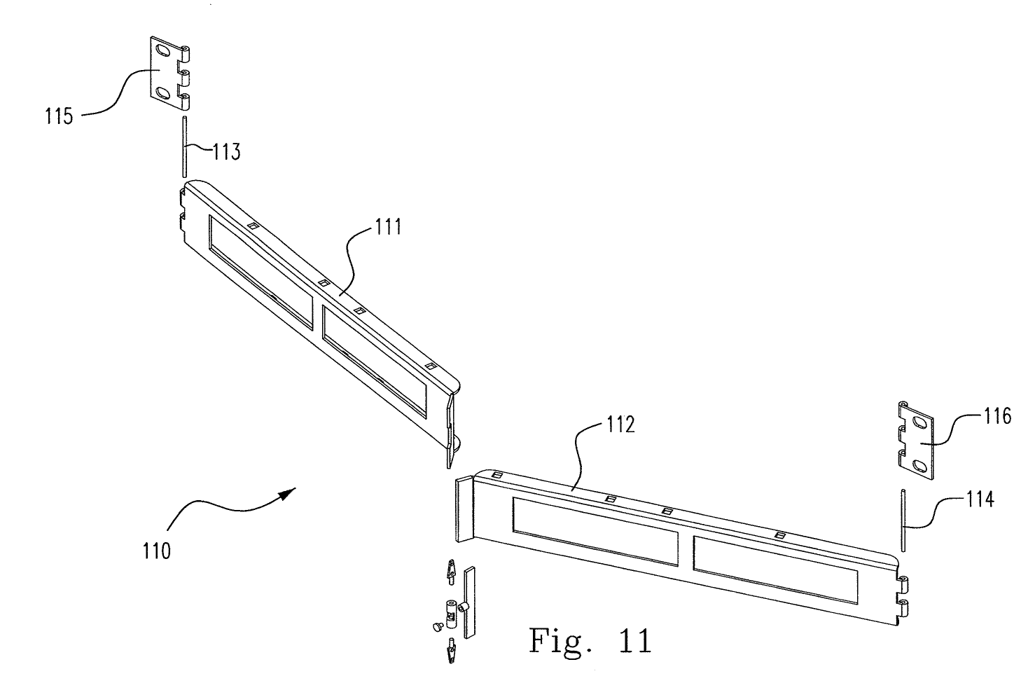

Referring to FIG. 10, according to another feasible point of view, the present invention is a rack 100 for mounting a network Hub, includes a rack body 101, and a panel device 30 mounted in rack body 101 including first elongated panel 31 and second elongated panel 32, wherein second elongated panel 32 is pivotally connected with first elongated panel 31. Patch panel 30 combined with cable support frame 44 is mounted on rack body 101. Referring to FIG. 11, which illustrates first elongated panel 111, second elongated panel 112, a left pin 113, a right pin 114, a left fixing piece 115 and a right fixing piece 116. And first and second elongated panels 31, 32 of rack 100 have a first and a second mounting parts 531, 532 respectively.

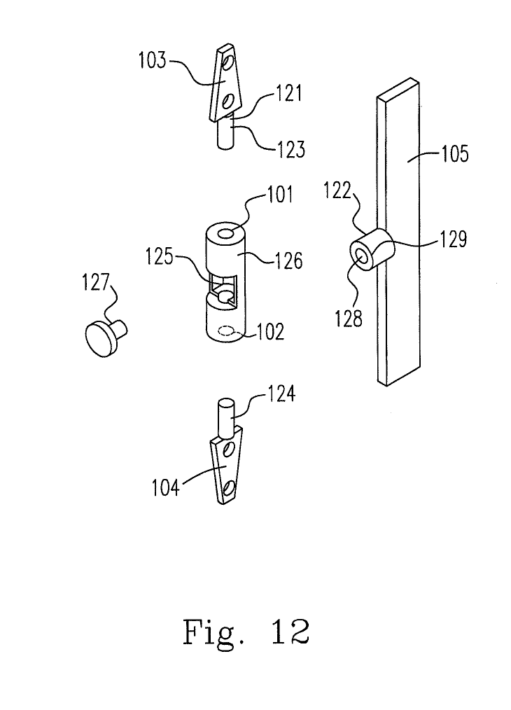

Referring to FIG. 12, patch panel 110 can use a first and a second pin 121, 122 for second elongated panel 112 to connect with first elongated panel 111 pivotally, first pin 121 includes an upper pin half 123, a central sleeve 126 and a lower pin half 124, central sleeve 126 has a first and a second apertures 101, 102, and first and second apertures 101, 102 are inserted by upper pin half 123 and lower pin half 134 respectively. Central sleeve 126 further includes a central aperture 125, second pin 122 includes an fixing pin 127 and a fixing fixture 129 having a fixing aperture 128, and fixing pin 127 and fixing fixture 129 are mounted into central aperture 125 for turning second elongated panel 112 with respect to first elongated panel 111. First pin 121 includes an upper fixing part 103 and a lower fixing part 104, second pin 122 includes a fixing plate 105, the upper fixing part and the lower fixing part are fixed on first elongated panel 111, and fixing plate 105 is fixed on second elongated panel 112.

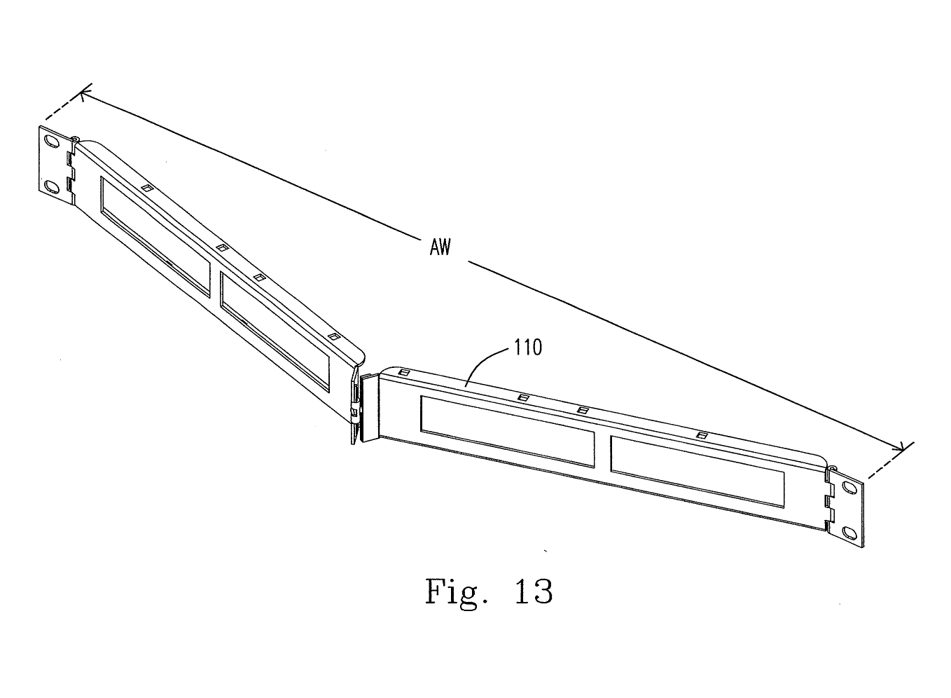

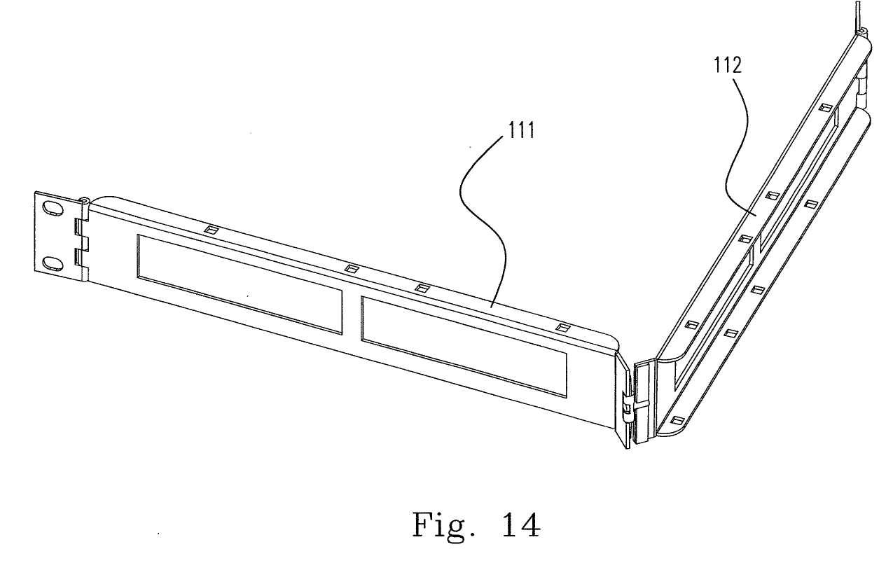

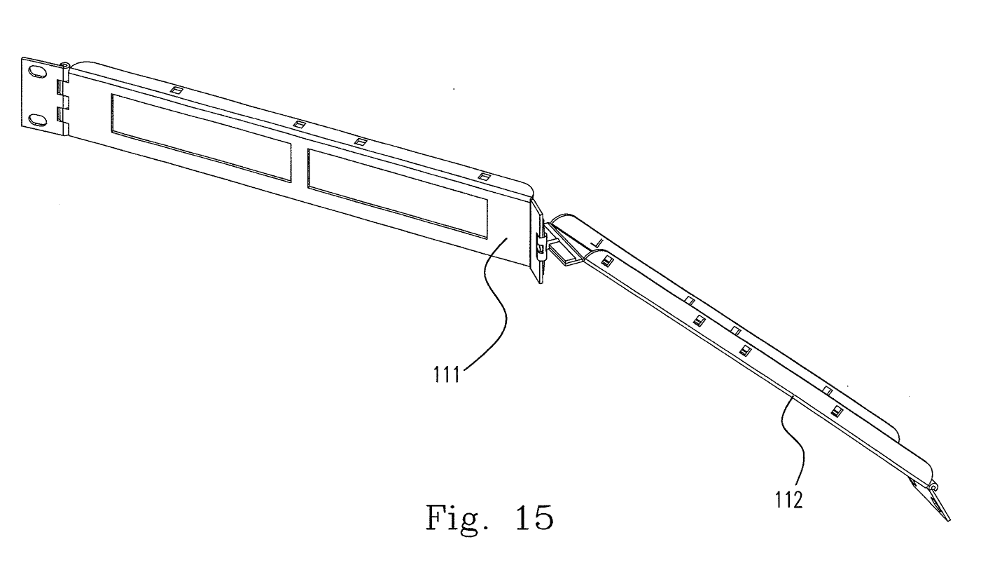

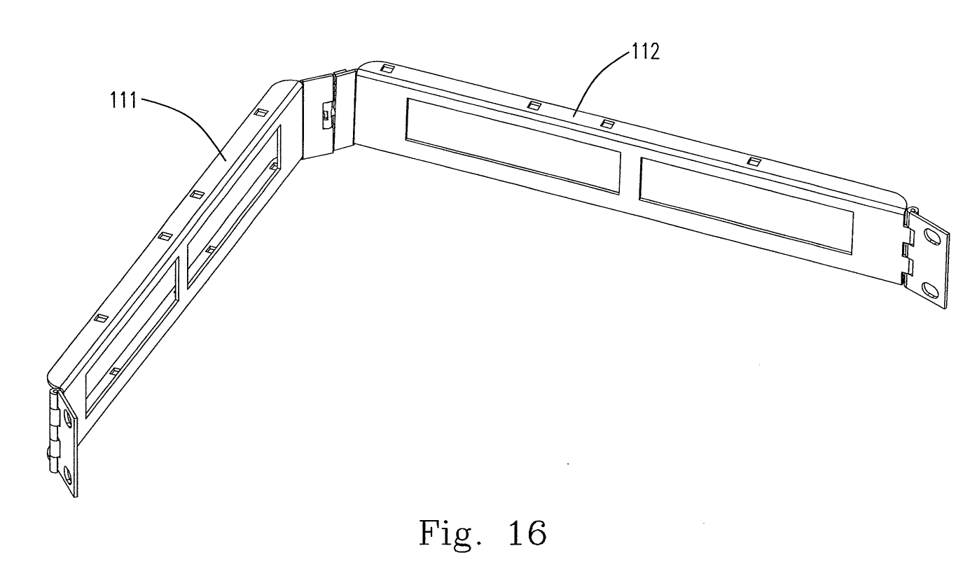

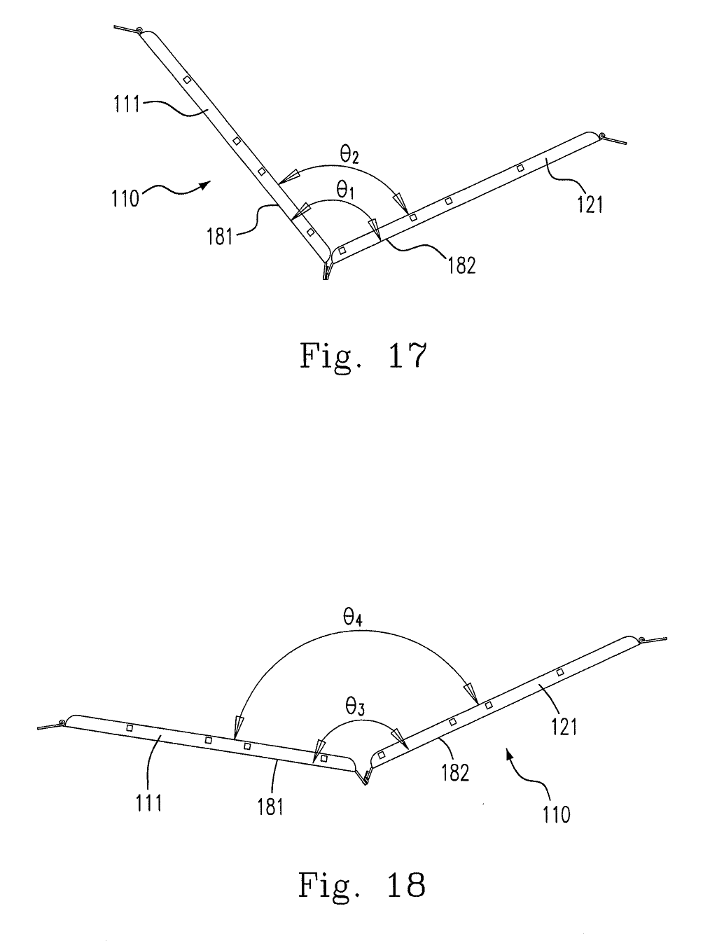

In regard to the diagram after the combination of the panel, it is shown in FIG. 13, left pin 113 and right pin 114 are used for flexibly adjusting an application width AW of patch panel 110 (e.g. adjusting the width of 19 inches (482.5 mm) into the width of 23 inches (584.2 mm)). First and second elongated panels 111, 112 are rotated via left pin 113 and right pin 114 respectively so as to adjust application width AW of patch panel 110 between 19 inch and 23 inch. And FIG. 14 and FIG. 15 illustrate conditions of a 180° turn and a 90° turn of second panel 112 by the axle center of second pin 122 respectively. A 145° included angle is formed by first elongated panel 111 and second elongated panel 112 in FIG. 16. Referring to FIG. 17, the included angle θ₁ is 104.24° and formed by a first face 181 of first elongated panel 111 and a second face 182 of second elongated panel 112, and meantime the width of patch panel 110 is 19 inches (moreover, the included angle θ₂ of the backs of two panels 111, 112 is 104.24°). And FIG. 18, the included angle θ₃ is 146.10° and formed by a first face 181 of first elongated panel 111 and a second face 182 of second elongated panel 112, and meantime the width of patch panel 110 is 23 inches (moreover, the included angle θ₄ of the backs of two panels 111, 112 is 146.10°).

In conclusion, a novel scheme is provided in the present invention where utilizes second elongated panel pivotally connected with the first elongated panel, then the second elongated panel being able to turn on the condition of the first elongated panel fixed, and the utilizing of a hinge connected the first and the second elongated panel pivotally is really able to revolve the single panel directly.

While the disclosure has been described in terms of what are presently considered to be the most practical and exemplary embodiments, it is to be understood that the disclosure need not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A panel device, comprising:
a first elongated panel having a first mounting part; and
a second elongated panel having a second mounting part and pivotally connected with the first elongated panel.

2. A device according to claim 1, wherein the panel device is a crooked patch panel so as to facilitate the second elongated panel to be rotated directly when the first elongated panel is immovably fixed.

3. A device according to claim 2 further comprising a hinge, wherein the crooked patch panel is a “V” shaped patch panel, and the first and the second elongated panels are connected pivotally by using the hinge.

4. A device according to claim 3, wherein the first elongated panel has a first holding part, the second elongated panel has a second holding part, and the hinge includes the first holding part, the second holding part and a first pin for combining the first and the second elongated panels to form the patch panel.

5. A device according to claim 4, wherein the first elongated panel further comprises a first main body and a first connecting part mounted between the first main body and the first holding part, a first obtuse angle is formed between the first connecting part and the first main body, the second elongated panel further comprises a second main body and a second connecting part mounted between the second main body and the second holding part, and a second obtuse angle is formed between the second connecting part and the second main body so that the first and the second elongated panels can be collapsed together.

6. A device according to claim 5 further comprising a 0°˜240° included angle, wherein the included angle is formed by the first and the second main body.

7. A device according to claim 4, wherein the first pin includes an upper pin half, a central sleeve and a lower pin half, the central sleeve has a first and a second apertures, and the first and the second apertures are inserted by the upper pin half and the lower pin half respectively.

8. A device according to claim 7 further comprising a second pin, wherein the central sleeve further comprises a central aperture, the second pin includes a fixing pin and a fixing fixture having a fixing aperture, and the fixing pin and the fixing fixture are mounted into the central aperture for turning the second elongated panel with respect to the first elongated panel.

9. A device according to claim 8, wherein the first pin comprises an upper fixing part and a lower fixing part, the second pin comprises a fixing plate, the upper fixing part and the lower fixing part are fixed on the first elongated panel, and the fixing plate is fixed on the second elongated panel.

10. A device according to claim 4 further comprising a left pin, a right pin, a left fixing piece and a right fixing piece for flexibly adjusting an application width of the patch panel.

11. A device according to claim 10, wherein the first and the second elongated panels are rotated via the left pin and the right pin respectively so as to adjust the application width of the patch panel between 19 inch and 23 inch.

12. A device according to claim 1, wherein the first and the second mounting parts are rectangular openings respectively, and plural keystone jacks are mounted into the rectangular openings.

13. A device according to claim 12, wherein the plural keystone jacks are arranged to be interlaced between a higher position and a lower position.

14. A device according to claim 1 further comprising a cable support frame for receiving plural network cables.

15. A device according to claim 14 further comprising a lock piece and a connecting rod for fixing the cable support frame on the device.

16. A device according to claim 1 further comprising a multimedia connector and a modular multi-port panel module mounted on the first and the second mounting parts respectively, wherein the modular multi-port panel module has an insulation displacement connector for connecting an external cable.

17. A method for manipulating a panel device having a first and a second elongated panels, each of which has at least a mounting part, the method comprises steps of:
pivotally connecting the first elongated panel with the second elongated panel;
determining a wiring demand; and
releasing one of the first and the second panels in response to the wiring demand so that the panel device is released in a more convenient way.

18. A method according to claim 17, wherein the wiring demand is a network wiring demand, and the network wiring demand includes a replacement of a keystone jack, a confirmation of a wire connection and an impact of the keystone jack.

19. A rack for mounting network Hub, comprising:
a rack body; and
a panel device mounted in the rack body and including a first and a second elongated panels, wherein the second elongated panel is pivotally connected with the first elongated panel.

20. A rack according to claim 19, wherein the first and the second elongated panels have a first and a second mounting parts respectively.
